(19) United States
(12) Patent Application Publication
(10) Pub. No.: US 2006/0091517 A1
(43) Pub. Date: May 4, 2006

(54) Stacked semiconductor multi-chip package

(75) Inventors: Jin O. Yoo, Suwon (KR); Yun Hwi Park, Suwon (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Kyungki-do (KR)

(21) Appl. No.: 11/092,308

(22) Filed: Mar. 29, 2005

(30) Foreign Application Priority Data
Oct. 29, 2004 (KR) 10-2004-86989

(51) Int. Cl. H01L 23/02

(52) U.S. Cl. 257/686

(57) ABSTRACT

Disclosed herein is a stacked semiconductor multi-chip package. The semiconductor multi-chip package comprises a substrate, a lower die mounted on an upper surface of the substrate to electrically connect to a circuit printed in a pattern on the substrate, an upper die electrically connected to the substrate via at least one conductive wire, and at least one metal layer stacked over an upper surface of the lower die, while allowing the upper die to be mounted on an upper surface of the metal layer, such that the metal layer may be connected to the upper die via at least one upper grounding wire while being connected to the substrate via at least one lower grounding wire. The package can release heat generated from the package to the outside, stably maintain a ground potential between the upper die and the substrate, and prevent mutual interference of noise signals between the upper and lower dies.

### RELATED APPLICATIONS

The present application is based on, and claims priority from, Korean Application Number 2004-86989, filed Oct. 29, 2004, the disclosure of which is incorporated by reference herein in its entirety.

### BACKGROUND OF THE INVENTION

1. Field of the Invention

The present invention relates to a multi-chip package in which two or more chips are encapsulated in a stacked state, and more particularly, to a stacked semiconductor multi-chip package, designed to release heat generated upon operation of the semiconductor device to the outside thereof, to stably maintain a ground potential between an upper die and a substrate, and to prevent mutual interference of noise signals between upper and lower dies.

2. Description of the Related Art

In recent years, as requirements for miniaturization, high capability, and multiple functions of a semiconductor chip package have been increased, it has been a trend in the field of semiconductor packaging to lower the size of the semiconductor package, and to increase the number of pins thereof. The semiconductor package can be classified into several types according to shapes of mount and lead of the semiconductor package, and generally includes Dual Inline Package (DIP), Small Outline Package (SOP), Shrink SOP (SSOP), Thin SOP (TSOP), J-head SOP (SOJ), Quad Flat Package (QFP), Plastic Leaded Chip Carrier-Square (PLCC-Square), PLCC-Rectangular, Ball Grid Array (BGA), Bottom Leader Plastic (BLP), and the like.

Additionally, a multi-chip packaging technology is known in which one package can have a plurality of semiconductor chips stacked on a printed circuit board, thereby providing a semiconductor module having a high capability. Here, a semiconductor multi-chip package means that at least two semiconductor dies are coupled to each other within a single package, and can be classified into a side-by-side semiconductor multi-chip package, a stacked semiconductor multi-chip package, and the like according to the coupled shapes of the semiconductor dies.

The side-by-side semiconductor multi-chip package has the semiconductor dies arranged adjacent to each other on at least one die-bonding pad, and the stacked semiconductor multi-chip package has the semiconductor dies consecutively stacked on the die-bonding pad.

FIGS. 1a and 1b are a cross-sectional view illustrating a conventional semiconductor multi-chip package, in which FIG. 1a shows a pyramid-stacked multi-chip package, and FIG. 1b show an overhang-stacked multi-chip package.

Referring to FIGS. 1a and 1b, the conventional semiconductor multi-ship package 10; 20 comprises a substrate 11; 21, and upper and lower semiconductor dies (which will be referred to as upper and lower dies) 14 and 15; 24 and 25 vertically stacked on the substrate 11; 21 via bonding members 12 and 13; 22 and 23.

Additionally, the upper and lower dies 14 and 15; 24 and 25 has a plurality of wire-bonding pads 14a and 15a; 24a and 25a formed along edges of upper surfaces thereof, respectively, and the substrate 11; 21 having the lower die 15; 25 mounted thereon has a plurality of wire-bonding pads (not shown) provided on an upper surface of the substrate 11; 21.

The lower die 15; 25 is stacked on the substrate 11; 21 via the bonding member 13; 23, such as a die-bonding film, and the upper die 14; 24 is stacked on the lower die 15; 25 via the other bonding member 12; 22.

The conventional semiconductor multi-ship package further comprises a plurality of conductive wires 16 and 17; 26 and 27 electrically connected at one end thereof to the wire-bonding pads 14a and 15a; 24a and 25a on the upper and lower dies 14 and 15; 24 and 25, and electrically connected at the other end thereof to the wire-bonding pads of the substrate 11; 21, respectively. At this time, the upper and lower dies 14 and 15; 24 and 25 may be prepared as one of memory chips, such as a Static Random Access Memory (SRAM) and a Dynamic Random Access Memory (DRAM), a digital integrated circuit chip (which will be referred to as a digital IC chip), and a Radio Frequency (RF) integrated circuit chip (which will be referred to as an RFIC chip).

The conventional semiconductor multi-ship package further comprises a molding portion 19; 29, which surrounds the upper and lower dies 14 and 15; 24 and 25, and the conductive wires 16 and 17; 26 and 27 on the substrate 11; 21 by use of epoxy molding compounds, in order to protect the upper and lower dies 14 and 15; 24 and 25, and the conductive wires 16 and 17; 26 and 27 from an external environment, such as damage caused by an external force, corrosion, and the like.

The substrate 11; 21 is provided at the lower surface thereof with a solder-ball array 18; 28 comprising a plurality of wire-bonding pads (not shown) spaced a predetermined distance apart from each other in an array for an electrical connection to the outside.

However, although heat is generated from the upper and lower dies 14 and 15; 24 and 25 upon operation of the semiconductor device after being implemented, since the conventional semiconductor multi-chip package 10; 20 structured as described above does not have an additional heat releasing body to release the heat to the outside thereof, there is a problem in that the heat generated from the upper and lower dies 14 and 15; 24 and 25 is accumulated within the package 10; 20, thereby increasing the thermal load in the device.

Meanwhile, ground terminals for respective ports of the upper die 14; 24 are connected to ground terminals of the substrate 11; 21 through the plurality of conductive wires 16 and 17; 26 and 27 electrically connected between the upper and lower dies 14 and 15; 24 and 25 and the substrate 11; 21. In this case, since the conductive wires 16; 26 are relatively longer than the conductive wires 17; 27 connecting the lower die 15; 24 and the substrate 11; 21, and a great amount of noise is generated during transmission of signals, ground potentials in the respective ports become different from each other, thereby causing an unstable operation of the semiconductor multi-chip package.

Additionally, upon operation of the semiconductor multi-chip package, the noise generated from the upper and lower dies 14 and 15; 24 and 25 to the outside has an influence against each other, and thus frequently causes abnormal operations, thereby reducing a reliability of the package products.

Additionally, the kind of semiconductor chip used for the upper and lower dies 14 and 15; 24 and 25 is limited to a special case in order to minimize the abnormal operations caused by mutual interference of the noise, thereby lowering a degree of freedom in manufacturing the package products.

### SUMMARY OF THE INVENTION

The present invention has been made to solve the above problems, and it is an object of the present invention to provide a stacked semiconductor multi-chip package, designed to release heat generated upon operation of the semiconductor device to the outside, to stably maintain a ground potential between an upper die and a substrate, and to prevent mutual interference of noise signals between upper and lower dies.

In accordance with one aspect of the present invention, the above and other objects can be accomplished by the provision of a stacked semiconductor multi-chip package, comprising: a substrate; a lower die mounted on an upper surface of the substrate to electrically connect to a circuit printed in a pattern on the substrate; an upper die electrically connected to the substrate via at least one conductive wire; and at least one metal layer stacked over an upper surface of the lower die, while allowing the upper die to be mounted on an upper surface of the metal layer, such that the metal layer may be connected to the upper die via at least one upper grounding wire while being connected to the substrate via at least one lower grounding wire.

The lower die may be bonded to the upper surface of the substrate by a flip-chip boding method.

The lower die may have an upper surface area larger than a lower surface area of the upper die.

The upper die may be mounted on the upper surface of the metal layer via a bonding member interposed between the metal layer and the upper die, and the bonding member may consist of a dielectric bonding agent or a dielectric die-bonding film.

The metal layer may be stacked over an overall upper surface of the lower die with a uniform thickness.

The upper die may have at least one wire-bonding pad for the upper die connected to the upper grounding wire while being correspondingly connected to ground terminals of the upper die, and the substrate may have at least one wire-bonding pad for the substrate connected to the lower grounding wire while being correspondingly connected to ground terminals of the substrate.

The stacked semiconductor multi-chip package may further comprise a molding portion surrounding the upper and lower dies, the metal layers, and the plurality of wires on the substrate in order to protect the upper and lower dies, the metal layers, and the plurality of wires.

In accordance with another aspect of the present invention, there is provided a stacked semiconductor multi-chip package, comprising: a substrate; a lower die mounted on an upper surface of the substrate to electrically connect to a circuit printed in a pattern on the substrate; an upper die electrically connected to the substrate via at least one conductive wire; and a metal cover provided on the substrate, while allowing the upper die to be mounted on an upper surface of the metal cover, such that the metal cover may be connected to the upper die via at least one upper grounding wire, while defining an inner space surrounding the lower die.

In this case, the lower die may be bonded to the upper surface of the substrate by a flip-chip boding method.

The upper and lower dies may have the same size.

The upper die may be mounted on the upper surface of the metal cover via a bonding member interposed between the metal cover and the upper die, and the bonding member may consist of a dielectric bonding agent or a dielectric die-bonding film.

The metal cover may comprise a square-shaped flat plane having a flat upper surface to allow the upper die to be mounted on the upper surface of the metal cover, and a vertical body vertically extended downward from an outside end of the square-shaped flat plane and fixed to the substrate.

The upper die may have at least one wire-bonding pad for the upper die connected to the upper grounding wire while being correspondingly connected to ground terminals of the upper die, and the metal cover may have a lower end correspondingly connected to ground terminals of the substrate.

The metal cover may have an inner surface corresponding to an outer surface of the lower die, and coated with a metal layer for shielding.

The stacked semiconductor multi-chip package may further comprise a molding portion surrounding the upper and lower dies, the metal cover, and the plurality of wires on the substrate in order to protect the upper and lower dies, the metal cover, and the plurality of wires.

In accordance with yet another aspect of the present invention, there is provided a stacked semiconductor multi-chip package, comprising: a substrate; a lower die mounted on an upper surface of the substrate to electrically connect to a circuit printed in a pattern on the substrate; an upper die electrically connected to the substrate via at least one conductive wire; and a metal cover provided on the substrate while allowing the upper die to be mounted on an upper surface of the metal cover, such that the metal cover may be connected to the upper die via at least soldering material, while defining an inner space surrounding the lower die.

In this case, the lower die may be bonded to the upper surface of the substrate by a flip-chip boding method.

The upper and lower dies may have the same size.

The metal cover may comprise a square-shaped flat plane having a flat upper surface to allow the upper die to be mounted on the upper surface of the metal cover, and a vertical body vertically extended downward from an outside end of the square-shaped flat plane and fixed to the substrate.

The soldering material may be connected to a ground terminal formed at a lower surface of the upper die, and the metal cover may have a lower end connected to a ground terminal of the substrate.

The metal cover may have an inner surface corresponding to an outer surface of the lower die and coated with a metal layer for shielding.

The stacked semiconductor multi-chip package may further comprise a molding portion surrounding the upper and lower dies, the metal cover, and the plurality of wires on the substrate in order to protect the upper and lower dies, the metal cover, and the plurality of wires.

### BRIEF DESCRIPTION OF THE DRAWINGS

The foregoing and other objects and features of the present invention will be more clearly understood from the following detailed description taken in conjunction with the accompanying drawings, in which:

FIGS. 1a and 1b are a cross-sectional view illustrating a conventional semiconductor multi-chip package, in which FIG. 1a shows a pyramid-stacked multi-chip package, and FIG. 1b show an overhang-stacked multi-chip pack-age;

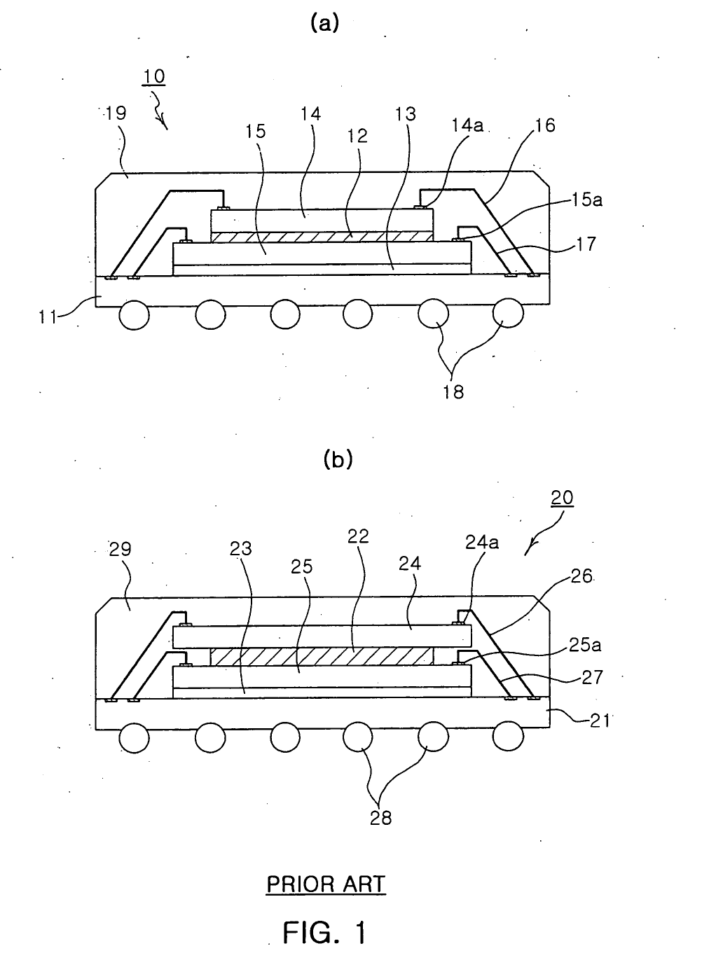

FIG. 2 is a cross-sectional view illustrating a stacked semiconductor multi-chip package in accordance with a first embodiment of the present invention;

FIG. 3 shows the overall construction of the stacked semiconductor multi-chip package in accordance with the first embodiment of the present invention;

FIG. 4 is a cross-sectional view illustrating a stacked semiconductor multi-chip package in accordance with a second embodiment of the present invention;

FIG. 5 shows the overall construction of the stacked semiconductor multi-chip package in accordance with the second embodiment of the present invention;

FIG. 6 is a cross-sectional view illustrating a stacked semiconductor multi-chip package in accordance with a third embodiment of the present invention; and

FIG. 7 shows the overall construction of the stacked semiconductor multi-chip package in accordance with the third embodiment of the present invention.

### DESCRIPTION OF THE PREFERRED EMBODIMENTS

Preferred embodiments will now be described in detail with reference to the accompanying drawings.

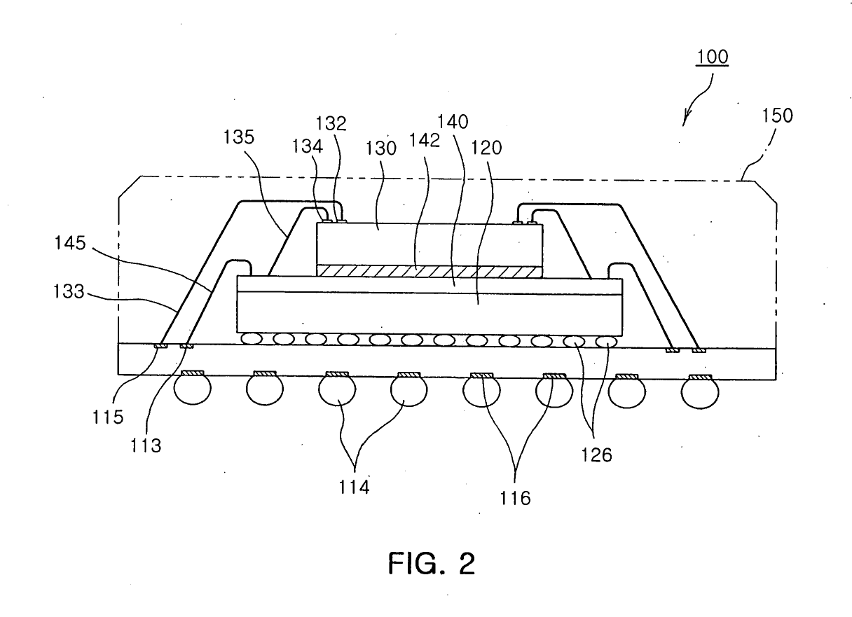

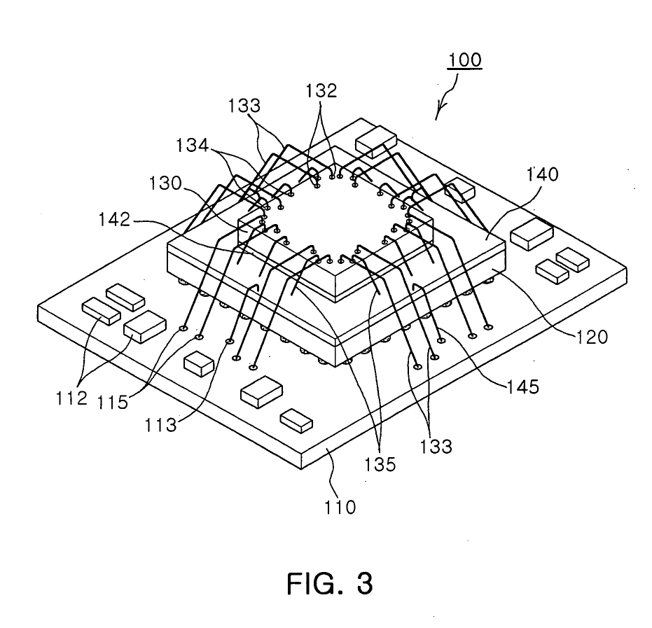

FIG. 2 is a cross-sectional view illustrating a stacked semiconductor multi-chip package in accordance with a first embodiment of the invention, and FIG. 3 shows the overall construction of the stacked semiconductor multi-chip package in accordance with the first embodiment of the invention.

The semiconductor multi-chip package of the invention is designed to release heat generated upon operation of the semiconductor device to the outside, to stably maintain a ground potential between an upper die and a substrate, and to prevent mutual interference of noise signals between upper and lower dies. Referring to FIGS. 2 and 3, the semiconductor multi-chip package of the invention comprises a substrate 110, a lower die 120, an upper die 130, and a metal layer 140.

The substrate 110 has circuits printed in various patterns on an upper surface thereof. The substrate 110 has a plurality of wire-bonding pads 113 and 115 formed thereon, and a plurality of electronic components 112 mounted thereon to correspond to the circuits.

The substrate 110 is provided at a lower surface thereof with a plurality of ball pads 114 uniformly spaced a predetermined distance apart from each other, and each of the ball pads is formed with a solder-ball 116 for an electrical connection to a main substrate (not shown), thereby allowing the substrate 110 to be mounted on the main substrate.

The lower die 120 is a chip component mounted on the upper surface of the substrate 110 such that the lower die 120 is electrically connected to the circuits printed in the patterns on the upper surface of the substrate 110. Like the substrate 110, the lower die 120 is also provided at a lower surface thereof with a plurality of ball pads, and each of the ball pads is formed with a solder ball 126, thereby allowing the lower die 120 to be bonded to the upper surface of the substrate by a flip-chip bonding method.

The upper die 130 stacked on an upper portion of the lower die 120 is a chip component, which is electrically connected to the substrate 110 via one or more conductive wires 133, each having one end thereof electrically connected to the associated wire-bonding pad 113 formed on the substrate 110.

The upper die 130 is formed with a plurality of wire-bonding pads 132 and 134 on an upper surface of the upper die 130. One of the wire-bonding pads 132 and 134 is connected to the other end of the associated conductive wire 133 having the one end electrically connected to the associated wire-bonding pad 113 of the substrate 110, and the other is connected to an associated one of upper grounding wires 135.

The metal layer 140 is at least one metallic conductor layer stacked on the upper surface of the lower die 120 with a uniform thickness. The metal layer 140 is connected to the upper die 130 via the upper grounding wires 135 in such a manner that each of the upper grounding wires 135 is connected at one end thereof to the associated wire-bonding pad 134 of the upper die 130 while being connected at the other end to the metal layer 140 by the flip-chip bonding method to form a wide ground equipotential area.

Additionally, the metal layer 140 is connected to the substrate 110 via one or more lower grounding wires 145 in such a manner that each of the lower grounding wires 145 is connected at one end thereof to the associated wire-bonding pad 115 of the substrate 110 while being connected at the other end to the metal layer 140 by the flip-chip bonding method to, thereby allowing the metal layer 140 to be grounded through the substrate 110.

Here, the wire-bonding pads 134 of the upper die 130 connected to the upper grounding wires 135 are correspondingly connected to ground terminals of the upper die 130, and the wire-bonding pads 115 of the substrate 110 connected to the lower grounding wires 145 are correspondingly connected to ground terminals of the substrate 110.

Each of the upper grounding wires 135 connected between the upper die 130 and the metal layer 140 may have the same length as that of each of the lower grounding wires 145 connected between the lower die 140 and the substrate 110.

The upper die 130 is bonded to the center of the upper surface of the metal layer 140 by means of a dielectric bonding member 142. The bonding member 142 may consist of a dielectric bonding agent or a dielectric die-bonding film, which is interposed between the upper surface of the metal layer 140 and the lower surface of the upper die 130, and then coated with a predetermined thickness to apply a bonding force therebetween.

Here, the metal layer 140 may be stacked over the overall upper surface of the lower die 120 to form the ground equipotential area as wide as possible near the upper die 130.

As such, the upper and lower dies 120 and 130 are vertically stacked with the metal layer 140 and the bonding member 142 interposed therebetween. The upper and lower dies 120 and 130 may be prepared as one of memory chips, such as SRAM and DRAM, a digital IC chip, and an RFIC chip. The lower die 120 has an upper surface area larger than a lower surface area of the upper die 130, in order to allow the metal layer 140 stacked on the upper surface of the lower die 120 to be exposed to the outside thereof.

The multi-chip package according to the first embodiment of the invention further comprises a molding portion 150 provided on the upper surface of the substrate 110 to surround the upper and lower dies 120 and 130, the metal layer 140, and the plurality of wires 133, 135 and 145 by means of epoxy molding compounds in order to protect them from an external force, corrosion, and the like.

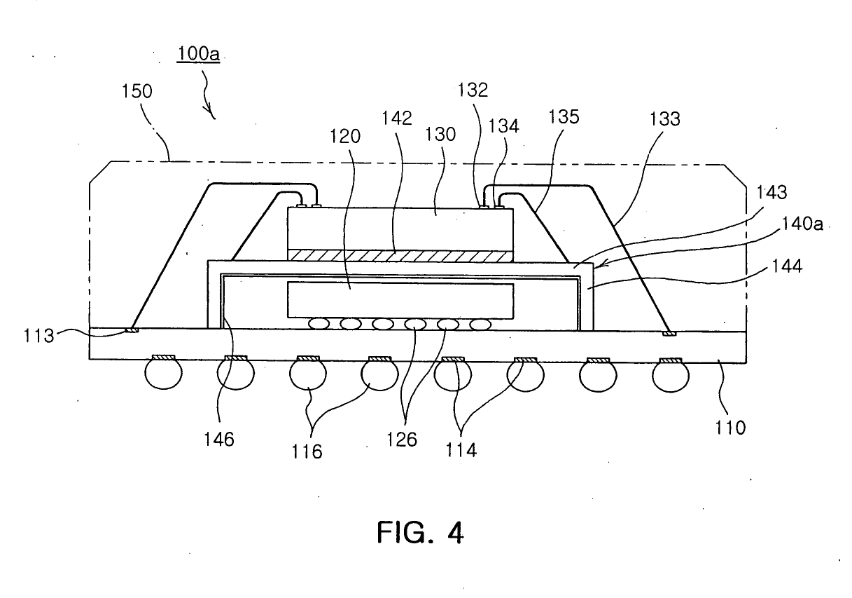

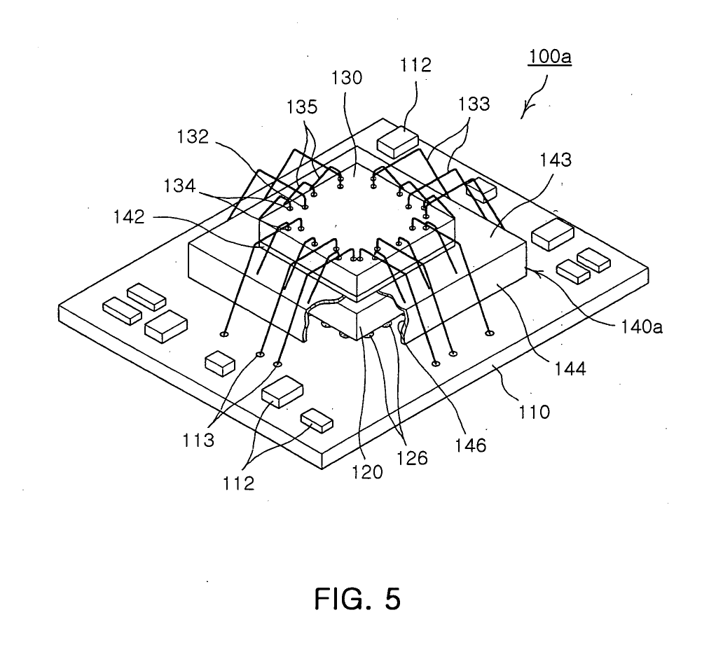

FIG. 4 is a cross-sectional view illustrating a stacked semiconductor multi-chip package in accordance with a second embodiment of the invention, and FIG. 5 shows the overall construction of the stacked semiconductor multi-chip package in accordance with the second embodiment of the invention. Referring to FIGS. 4 and 5, a package 100a of the invention comprises a substrate 110, upper and lower dies 120 and 130, and a metal cover 140a. The same components of the second embodiment as those of the first embodiment will be denoted by the same reference numerals as those of the first embodiment, and detailed description thereof will be omitted hereinafter.

The metal cover 140a is a metallic member, which has a rectangular parallelepiped-box shape having a lower portion opened while defining an inner space surrounding a lower die 120 mounted on an upper surface of the substrate 110, and has a lower end fixed to the upper surface of the substrate 110.

The metal cover 140a comprises a square-shaped flat plane 143 having a flat upper surface to allow the upper die 130 to be mounted on the upper surface of the metal cover 140a, and a vertical body 144 vertically extended downward from an outside end of the square-shaped flat plane 143 while being fixed to the substrate 110.

The upper die 130 is bonded to an upper surface of the square-shaped flat plane 143 of the metal cover 140a via a bonding member 142. The bonding member 142 may consist of a dielectric bonding agent or a dielectric die-bonding film, which is interposed between the upper surface of the metal cover 140a and the lower surface of the upper die 130, and then coated with a predetermined thickness to apply a bonding force therebetween.

The metal cover 140a is connected to the upper die 130 via one or more upper grounding wires 135 so as to form a wide ground equipotential area near the upper die 130, and each of the upper grounding wires 135 is connected at one end thereof to an associated wire-bonding pad 134 of the upper die 130.

Here, the wire-bonding pads 134 of the upper die 130 connected to the upper grounding wires 135 are correspondingly connected to ground terminals of the upper die 130, and a lower end of the metal cover 140a is correspondingly connected to ground terminals of the substrate 110.

The metal cover 140a has an inner surface, which corresponds to an outer surface of the lower die 120 and may have a shielding layer 146 coated thereon with a predetermined thickness in order to shield detrimental electromagnetic waves generated by the lower die from being released to the outside.

The lower die 120 disposed within the inner space of the metal cover 140a has an upper surface area larger than a lower surface area of the upper die 130 mounted oh the upper surface of the metal cover 140a.

Meanwhile, like the first embodiment, the package 100a according to the second embodiment of the invention further comprises a molding portion 150 provided on the upper surface of the substrate 110 to encapsulate the upper and lower dies 120 and 130, the metal cover 140a, and the plurality of wires 133 and 135 in order to protect them from an external environment.

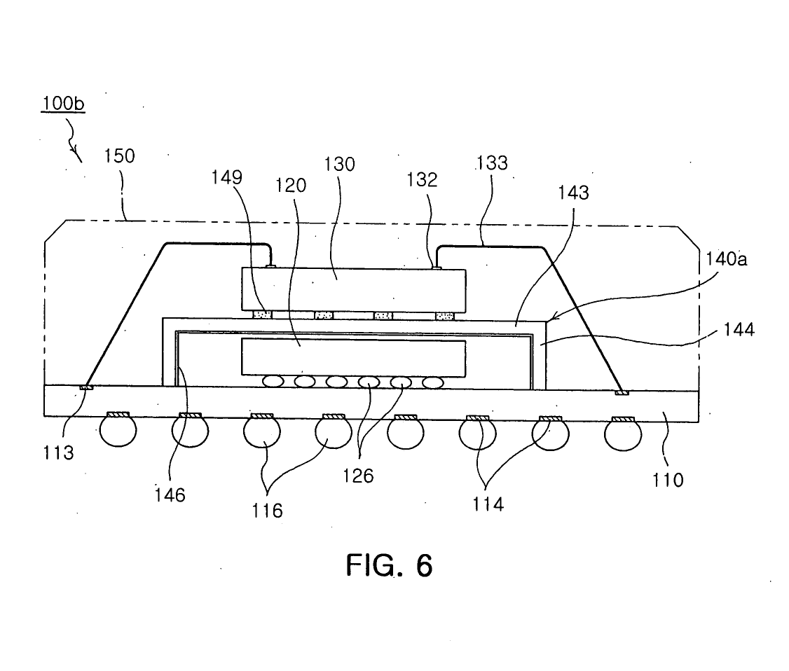

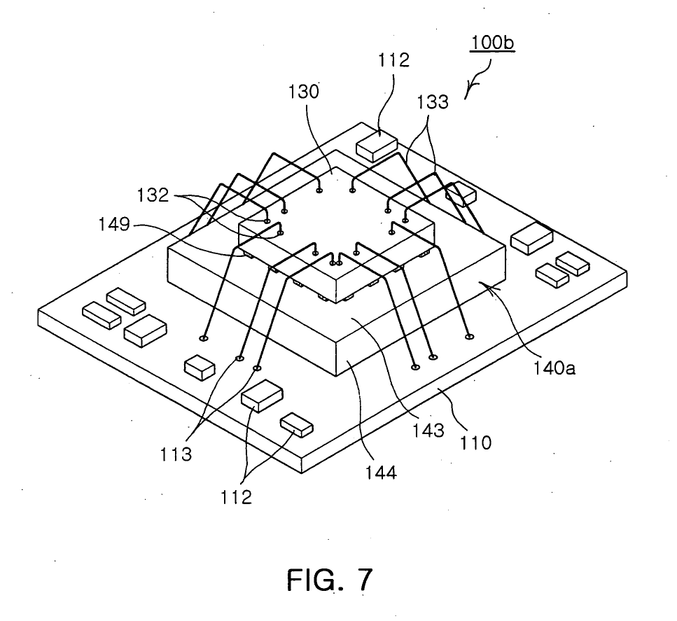

FIG. 6 is a cross-sectional view illustrating a stacked semiconductor multi-chip package in accordance with a third embodiment of the present invention, and FIG. 7 shows the overall construction of the stacked semiconductor multi-chip package in accordance with the third embodiment of the present invention. Referring to FIGS. 6 and 7, a package 100b of the invention comprises a substrate 110, lower and upper dies 120 and 130, and a metal cover 140a. The same components of the third embodiment as those of the first embodiment will be denoted by the same reference numerals as those of the first embodiment, and detailed description thereof will be omitted hereinafter.

The upper die 130 is located above the metal cover 140a, and is then fixed onto an upper surface of a square-shaped flat plane 143 of the metal cover 140a via one or more soldering materials 149. The soldering materials 149 correspond to one or more grounding terminals under a lower surface of the upper die 130.

Here, the soldering materials 149 are preferably made of a conductive material, which serves to generate a fixing force between the lower surface of the upper die 130 and the upper surface of the metal cover 140a while electrically connecting the upper die 130 and the metal cover 140a.

As a result, as shown in FIGS. 6 and 7, instead of the wire-bonding pads connected to the metal cover 140 via the at least one upper grounding wire 135, the upper die 130 can be formed with a ground equipotential area as wide as possible near the upper die 130 by means of the soldering materials 149, which are electrically connected to the metal cover 140a.

Upon operations of the multi-chip package 100; 100a; and 100b having the previously described construction, if heat is generated from the upper and lower dies 120 and 130 vertically stacked above the substrate 110, the heat is transferred to the metal layer 140 or the metal cover 140a made of a material having a positive thermal conductivity, and then released to the outside through a wide surface area of the metal layer 140 or the metal cover 140a.

As a result, upon operations of the multi-chip package 100; 100a; and 100b mounted on the main substrate, the heat generated from the upper and lower dies 120 and 130 is effectively released to the outside through the metal layer 140 or the metal cover 140a, thereby preventing the upper and lower dies 120 and 130 from being rapidly overheated or from being thermally damaged by accumulated heat.

Furthermore, although noise signals are emitted to the outside along with detrimental electromagnetic waves upon operations of the upper and lower dies 120 and 130, the metal layer 140 or the metal cover 140a, which is made of the metallic material having a higher shielding capability, can effectively shield the lower die 120 from being influenced by the noise signals emitted from the adjacent upper die 130 to the outside and vice versa, shield the upper die 130 from being influenced by the noise signals emitted from the adjacent lower die 120. At the same time, the detrimental electromagnetic waves emitted from the lower die 120 to the outside and vice versa can be completely or partially shielded by the metal layer 140 or the metal cover 140a.

Accordingly, the noise signals and the detrimental electromagnetic waves emitted from the upper and lower dies 120 and 130 upon operations of the multi-chip package 100; 100a; and 100b mounted on the main substrate can be shielded by means of the metal layer 140 and the metal cover 140a to suppress the mutual interference thereof, thereby enhancing the reliability of the products.

Additionally, the multi-chip package of the present invention may also have such a stacking construction wherein the lower die 120 which is very sensitive to signal interference, is prepared as the digital IC chip, and wherein the upper die 130 is prepared as the RFIC chip, thereby increasing a degree of freedom in design of the package.

As described above, the metal layer 140 or the metal cover 140a is formed between the upper die 130 and the lower die 120 such that a wide equipotential area can be formed near the upper die 130. The upper die 130 is connected to the metal layer 140 or the metal cover 140a for the ground via one of the upper grounding wire 135 and the soldering material 149, and the metal layer 140 is connected to the substrate 110 for the ground via the lower grounding wire 145. Subsequently, the metal cover 140a is directly connected to the substrate 110 for the ground.

Accordingly, since the length of the upper grounding wire 135 connected for the ground between the respective ground terminals of the upper die 130 and the metal layer 140 or the metal cover 140a is relatively short compared with the length of the lower grounding wire 145 connected to the substrate through the flip-chip bonding method, the ground potential in the package is prevented from being unstable, thereby achieving a stable electric property.

Additionally, the respective ground terminals of the upper die 130 are electrically connected to the metal cover 140a via the soldering materials 149, preventing the ground potential from being unstable due to the length of the wires upon wire bonding, thereby achieving a stable electric property.

As apparent from the above description, according to the present invention, the metal layer or the metal cover is provided between the lower die mounted on the substrate and the upper die connected to the substrate via the conductive wires, or the soldering materials are provided between the upper die and the metal layer or the metal cover. Accordingly, the metal cover or the metal layer effectively releases the heat generated from the upper and lower dies to the outside, preventing the overheat of the package, and shields the noise signals from being mutually interfered, preventing the abnormal operation of the multi-chip package. Additionally, the metal cover or the metal layer prevents the detrimental electromagnetic waves from being emitted to the outside while supplying the wide equipotential area, thereby enhancing the ground capability of the package. As a result, the life cycle of the package can be extended, the reliability of the package products can be enhanced, and the stable electric property of the products can be achieved.

It should be understood that the embodiments and the accompanying drawings as described above have been described for illustrative purposes and the present invention is limited by the following claims. Further, those skilled in the art will appreciate that various modifications, additions and substitutions are allowed without departing from the scope and spirit of the invention as set forth in the accompanying claims.

What is claimed is:

1. A stacked semiconductor multi-chip package, comprising:
a substrate;
a lower die mounted on an upper surface of the substrate to electrically connect to a circuit printed in a pattern on the substrate;
an upper die electrically connected to the substrate via at least one conductive wire; and
at least one metal layer stacked over an upper surface of the lower die, while allowing the upper die to be mounted on an upper surface of the metal layer, such that the metal layer may be connected to the upper die via at least one upper grounding wire while being connected to the substrate via at least one lower grounding wire.

2. The semiconductor multi-chip package as set forth in claim 1, wherein the lower die is bonded to the upper surface of the substrate by a flip-chip boding method.

3. The semiconductor multi-chip package as set forth in claim 1, wherein the lower die has an upper surface area larger than a lower surface area of the upper die.

4. The semiconductor multi-chip package as set forth in claim 1, wherein the upper die is mounted on the upper surface of the metal layer via a bonding member interposed between the metal layer and the upper die.

5. The semiconductor multi-chip package as set forth in claim 4, wherein the bonding member consists of a dielectric bonding agent.

6. The semiconductor multi-chip package as set forth in claim 4, wherein the bonding member consists of a dielectric die-bonding film

7. The semiconductor multi-chip package as set forth in claim 1, wherein the metal layer is stacked over an overall upper surface of the lower die with a uniform thickness.

8. The semiconductor multi-chip package as set forth in claim 1, wherein the upper die has at least one wire-bonding pad for the upper die connected to the upper grounding wire while being correspondingly connected to ground terminals of the upper die, and the substrate has at least one wire-bonding pad for the substrate connected to the lower grounding wire while being correspondingly connected to ground terminals of the substrate.

9. The semiconductor multi-chip package as set forth in claim 1, further comprising:
a molding portion surrounding the upper and lower dies, the metal layer, and the plurality of wires on the substrate in order to protect the upper and lower dies, the metal layer, and the plurality of wires.

10. A stacked semiconductor multi-chip package, comprising:
a substrate;
a lower die mounted on an upper surface of the substrate to electrically connect to a circuit printed in a pattern on the substrate;
an upper die electrically connected to the substrate via at least one conductive wire; and
a metal cover provided on the substrate while allowing the upper die to be mounted on an upper surface of the metal cover, such that the metal cover may be connected to the upper die via at least one upper grounding wire, while defining an inner space surrounding the lower die.

11. The semiconductor multi-chip package as set forth in claim 10, wherein the lower die is bonded to the upper surface of the substrate by a flip-chip boding method.

12. The semiconductor multi-chip package as set forth in claim 10, wherein the upper and lower dies have the same size.

13. The semiconductor multi-chip package as set forth in claim 10, wherein the upper die is mounted on the upper surface of the metal layer via a bonding member interposed between the metal cover and the upper die.

14. The semiconductor multi-chip package as set forth in claim 13, wherein the bonding member consists of a dielectric bonding agent.

15. The semiconductor multi-chip package as set forth in claim 13, wherein the bonding member consists of a dielectric die-bonding film.

16. The semiconductor multi-chip package as set forth in claim 10, wherein the metal cover comprises a square-shaped flat plane having a flat upper surface to allow the upper die to be mounted on the upper surface of the metal cover, and a vertical body vertically extended downward from an outside end of the square-shaped flat plane and fixed to the substrate.

17. The semiconductor multi-chip package as set forth in claim 10, wherein the upper die has at least one wire-bonding pad for the upper die connected to the upper grounding wire while being correspondingly connected to ground terminals of the upper die, and the metal cover has a lower end correspondingly connected to ground terminals of the substrate.

18. The semiconductor multi-chip package as set forth in claim 10, wherein the metal cover has an inner surface corresponding to an outer surface of the lower die, and coated with a shielding layer.

19. The semiconductor multi-chip package as set forth in claim 10, further comprising:
a molding portion surrounding the upper and lower dies, the metal cover, and the plurality of wires on the substrate in order to protect the upper and lower dies, the metal cover, and the plurality of wires.

20. A stacked semiconductor multi-chip package, comprising:
a substrate;
a lower die mounted on an upper surface of the substrate to electrically connect to a circuit printed in a pattern on the substrate;
an upper die electrically connected to the substrate via at least one conductive wire; and
a metal cover provided on the substrate while allowing the upper die to be mounted on an upper surface of the metal cover, such that the metal cover may be connected to the upper die via one or more soldering materials, while defining an inner space surrounding the lower die.

21. The semiconductor multi-chip package as set forth in claim 20, wherein the lower die is bonded to the upper surface of the substrate by a flip-chip boding method.

22. The semiconductor multi-chip package as set forth in claim 20, wherein the upper and lower dies have the same size.

23. The semiconductor multi-chip package as set forth in claim 20, wherein the metal cover comprise a square-shaped flat plane having a flat upper surface to allow the upper die to be mounted on the upper surface of the metal cover, and a vertical body vertically extended downward from an outside end of the square-shaped flat plane and fixed to the substrate.

24. The semiconductor multi-chip package as set forth in claim 20, wherein the soldering materials are connected to ground terminals formed at a lower surface of the upper die, and the metal cover has a lower end connected to ground terminals of the substrate.

25. The semiconductor multi-chip package as set forth in claim 20, wherein the metal cover has an inner surface corresponding to an outer surface of the lower die and coated with a shielding layer.

26. The semiconductor multi-chip package as set forth in claim 20, further comprising:
a molding portion surrounding the upper and lower dies, the metal cover, and the plurality of wires on the substrate in order to protect the upper and lower dies, the metal cover, and the plurality of wires.
